(19) United States
(12) Patent Application Publication
(10) Pub. No.: US 2013/0021688 A1
(43) Pub. Date: Jan. 24, 2013

(54) COLOR FILTER AND MANUFACTURING METHOD THEREOF

(71) Applicant: Chun-ming Wu, Shenzhen (CN)

(72) Inventor: Chun-ming Wu, Shenzhen (CN)

(73) Assignee: SHENZHEN CHINA STAR OPTOELECTRONICS TECHNOLOGY CO., LTD, Shenzhen, Guangdong (CN)

(21) Appl. No.: 13/260,226

(22) PCT Filed: Aug. 26, 2011
(86) PCT No.: PCT/CN11/78971

§ 371 Date: Sep. 23, 2011

(30) Foreign Application Priority Data
Jul. 22, 2011 (CN) 201110206444.7

(51) Int. Cl. G02B 5/22; B05D 5/12; G03F 7/20; B05D 5/06

(52) U.S. Cl. 359/891; 427/162; 427/58; 430/325

(57) ABSTRACT

The present invention provides a color filter and a manufacturing method of the color filter. The color filter comprises first color resist units and second color resist units, and a pixel layer is formed by the first color resist units and the second color resist units. The manufacturing method comprises the following step of: after the first color resist units are formed, forming photo spacers for controlling a gap between an array substrate and a color filter substrate simultaneously when the second color resist units are formed. The present invention can reduce the number of manufacturing processes and effectively reduce the manufacturing cost of liquid crystal displays (LCDs).

### BACKGROUND OF THE INVENTION

1. Technical Field

The present invention relates to a manufacturing method of a color filter, and more particularly, to a color filter provided with photo spacers in a liquid crystal display (LCD) and a manufacturing method of the color filter.

2. Description of Related Art

In the conventional process for manufacturing a color filter, spacers are generally disposed in such a way that a spacer layer of a uniform height is disposed in a selected color photoresist area of a color resist unit region to form a spacer for liquid crystal filling. However, the spacer layer is of a uniform height and the surface of a thin film transistor (TFT) layer to which the color filter is attached usually has a nonuniform height, both the rotating time and the recovery time of liquid crystals are different in the attachment area of varying heights when the color filter is attached to the TFT layer, thereby incurring problems in displaying.

In view of this, in an improved process for manufacturing spacers, an auxiliary spacer layer of a varying height is further formed in addition to the original spacer layer, which can overcome the shortcoming that different rotating time and recovery time are caused due to the height difference. Furthermore, because of the spacers additionally provided, the amount of liquid crystals needed to be filled when the panel is attached is reduced. However, this process for manufacturing a color filter is complex, has a lot of process steps and requires the use of many apparatuses, so it suffers from a high cost and a low efficiency.

### BRIEF SUMMARY OF THE INVENTION

The primary objective of the present invention is to provide a color filter and a manufacturing method of the color filter that can simplify the manufacturing process and improve the production efficiency.

To achieve the aforesaid objective, the present invention provides a manufacturing method of a color filter. The color filter comprises first color resist units and second color resist units, and a pixel layer is formed by the first color resist units and the second color resist units. The manufacturing method comprises the following step of:

after the first color resist units are formed, forming photo spacers for controlling a gap between an array substrate and a color filter substrate simultaneously when the second color resist units are formed.

Preferably, the step of forming photo spacers for controlling a gap between an array substrate and a color filter substrate simultaneously when the second color resist units are formed comprises:

forming the photo spacers on regions where the first color resist units overlap black matrix units.

Preferably, the step of forming photo spacers for controlling a gap between an array substrate and a color filter substrate simultaneously when the second color resist units are formed comprises:

disposing apertures for forming the photo spacers in a photomask for forming the second color resist units.

Preferably, the step of forming the photo spacers on regions where the first color resist units overlap black matrix units comprises:

in the photomask for forming the second color resist units, disposing apertures in areas corresponding to the regions where the first color resist units overlap the black matrix units.

The present invention further provides a manufacturing method of a color filter. The color filter comprises first color resist units, second color resist units and third color resist units, and a color pixel layer is formed by the first color resist units, the second color resist units and the third color resist units. The manufacturing method comprises the following steps of:

providing a transparent substrate;

forming black matrix units on the transparent substrate;

forming the first color resist units;

forming the second color resist units, and forming first photo spacers on the first color resist units simultaneously during formation of the second color resist units; and

forming the third color resist units, and forming second photo spacers on the second color resist units simultaneously during formation of the third color resist units.

Preferably, the step of forming the second color resist units and forming first photo spacers on the first color resist units simultaneously during formation of the second color resist units comprises the following steps of:

coating a layer of a second photoresist material on surfaces of the first color resist units, the black matrix units and the transparent substrate;

carrying out a vacuum drying process;

carrying out a pre-baking and cooling process;

disposing a photomask above the second photoresist material for exposure, wherein the photomask is formed with apertures for forming the second color resist units and the first photo spacers; and

carrying out a developing and baking process to form the second color resist units and the first photo spacers.

Preferably, the step of forming the third color resist units and forming second photo spacers on the second color resist units simultaneously during formation of the third color resist units comprises the following steps of:

coating a layer of a third photoresist material on surfaces of the first color resist units, the second color resist units, the first photo spacers, the black matrix units and the transparent substrate;

carrying out a vacuum drying process;

carrying out a pre-baking and cooling process;

disposing a photomask above the third photoresist material for exposure, wherein the photomask is formed with apertures for forming the third color resist units and the second photo spacers; and

carrying out a developing process to form the third color resist units and the second photo spacers.

Preferably, when the photomask is disposed for exposure, a height of the first photo spacers or the second photo spacers is controlled by adjusting an aperture ratio or an aperture transmissivity of the photomask.

Preferably, the manufacturing method comprises: forming the first photo spacers on regions where the first color resist units overlap the black matrix units, and forming the second photo spacers on regions where the second color resist units overlap the black matrix units.

Preferably, the step of forming the first photo spacers on regions where the first color resist units overlap the black matrix units comprises:

in the photomask for forming the second color resist units, disposing apertures in areas corresponding to the regions where the first color resist units overlap the black matrix units.

Preferably, the step of forming the second photo spacers on regions where the second color resist units overlap the black matrix units comprises:

in the photomask for forming the third color resist units, disposing apertures in areas corresponding to the regions where the second color resist units overlap the black matrix units.

Preferably, the manufacturing method further comprises the following steps of:

forming a transparent conductive layer on surfaces of the first color resist units, the second color resist units, the third color resist units, the first photo spacers and the second photo spacers; and

forming a transparent insulation layer on the transparent conductive layer.

The present invention further provides a color filter, which comprises:

a substrate;

a plurality of black matrix units, being disposed on the substrate in an array form, wherein gaps exist between adjacent ones of the black matrix units;

a plurality of first color resist units, a plurality of second color resist units and a plurality of third color resist units, being located in the gaps between the black matrix units and disposed adjacent to each other in sequence to form a pixel layer;

first photo spacers, being formed on surfaces of the first color resist units when the second color resist units are formed, and being located in regions where the first color resist units overlap the black matrix units;

second photo spacers, being formed on surfaces of the second color resist units when the third color resist units are formed, and being located in regions where the second color resist units overlap the black matrix units;

a transparent conductive layer covering the surfaces of the first color resist units, the second color resist units, the third color resist units, the first photo spacers and the second photo spacers; and

a transparent insulation layer covering the transparent conductive layer.

Preferably, a total height of one of the first photo spacers and one of the first color resist units is different from a total height of one of the second photo spacers and one of the second color resist units.

Preferably, each of the first photo spacers and the second photo spacers is in the form of a frustum of cone which is narrow at the top but wide at the bottom.

In the manufacturing method of a color filter according to the present invention, the function of original spacers can be replaced by forming on the first color resist units photo spacers for controlling a gap between an array substrate and a color filter substrate simultaneously when the second color resist units are formed. If each pixel unit of the color filter has three color resist units, then two photo spacers of different heights are formed on the three color resist units according to the aforesaid steps. The photo spacer of a higher height can function in place of the original main spacer layer, and the photo spacer of a lower height can function in place of the auxiliary spacer layer. Apart from eliminating the use of a photolithography process for forming the original spacers, this method can further reduce the differences in the rotating time and the recovery time and decrease the amount of liquid crystals to be filled.

### BRIEF DESCRIPTION OF THE SEVERAL VIEWS OF THE DRAWINGS

FIG. 1 is a schematic view illustrating a process flow of forming photo spacers in a manufacturing method of a color filter according to the present invention;

FIG. 2 is a flowchart illustrating a first embodiment of the manufacturing method of a color filter according to the present invention;

FIGS. 3a to 3g are schematic views illustrating a process flow of the manufacturing method shown in FIG. 2;

FIG. 4 is a flowchart illustrating a second embodiment of the manufacturing method of a color filter according to the present invention;

FIG. 5 is a flowchart illustrating a third embodiment of the manufacturing method of a color filter according to the present invention; and

FIGS. 6a to 6h are schematic views illustrating a process flow of the manufacturing method shown in FIG. 5.

Means adopted to achieve the objectives, as well as functions and advantages of the present invention will be further described hereinafter with reference to embodiments thereof and the attached drawings.

### DETAILED DESCRIPTION OF THE INVENTION

It shall be appreciated that, the embodiments described herein are only intended to illustrate but not to limit the present invention.

The present invention provides a manufacturing method of a color filter. The color filter comprises first color resist units and second color resist units. Each of the first color resist units and second color resist units is used as a sub-pixel respectively for forming a pixel unit. A pixel layer for use in a color filter of a liquid crystal display (LCD) is formed by a number of pixel units arranged in an array form. The manufacturing method of a color filter mainly comprises the following step of:

after the first color resist units are formed, forming photo spacers for controlling a gap between an array substrate and a color filter substrate simultaneously when the second color resist units are formed. In this embodiment, in addition to the first color resist units and the second color resist units, the color filter further comprises a substrate and black matrix units. The black matrix units are covered on the substrate in an array form, and function as a light shading layer to prevent leakage of light rays. Gaps exist between adjacent ones of the black matrix units. The first color resist units and the second color resist units are disposed in the corresponding gaps of the black matrix units respectively. In this embodiment, the first color resist units and the second color resist units may be formed through a pigment dispersion process, which comprises the following steps of:

firstly, coating a color photoresist layer (i.e., a layer of a first photoresist material) on the black matrix units and the substrate;

carrying out a vacuum drying process and removing the excessive first photoresist material at the edges;

carrying out a pre-baking and cooling process, and then disposing a photomask above the photo layer, wherein the photomask is formed with apertures in positions where the first color resist units need to be kept (e.g., positions between two black matrix units);

then, exposing the photoresist material to ultraviolet rays through the photomask;

carrying out a developing process and removing the unnecessary photoresist material; and

carrying out a baking process to form the first color resist units at positions corresponding to the positions of the apertures. Of course, the present invention may also adopt the lithography process, the transfer printing process or the like in the prior art to form the first color resist units, but is not limited to the aforesaid pigment dispersion process. The second color resist units are formed in a way similar to the first color resist units:

firstly, coating a color photoresist layer (i.e., a layer of a second photoresist material) on surfaces of the first color resist units, the black matrix units and the glass substrate;

carrying out a vacuum drying process and removing the excessive second photoresist material at the edges;

carrying out a pre-baking and cooling process, and then disposing a photomask above the photo layer, wherein the photomask is formed with apertures in positions where the second color resist units need to be kept (e.g., positions between two black matrix units that are adjacent to a side of the first color resist units);

carrying out a developing process and removing the unnecessary second photoresist material; and

carrying out a baking process to form the second color resist units in positions below the corresponding apertures.

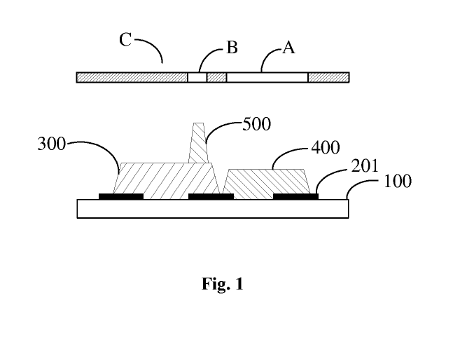

Specifically, referring to FIG. 1, there is shown a schematic view illustrating a process flow of forming photo spacers in the manufacturing method of a color filter according to the present invention. As shown in FIG. 1, each pixel unit of the color filter comprises a transparent substrate 100, a number of black matrix units 201, a first color resist units 300, a second color resist units 400 and a photo spacer 500. When the second color resist units 400 is formed and specifically, when a photomask C for forming the second color resist units 400 is placed, a smaller aperture B is further formed in the photomask C in addition to an aperture A for forming the second color resist units 400. The aperture B may be disposed at any position corresponding to the pixel unit as necessary; however, in order to obtain a better aperture ratio, the aperture B is preferably formed at a position corresponding to a region where the first color resist units overlaps one of the black matrix units. The aperture B may be formed into a circular shape, an elliptical shape, a polygonal shape or some other shape, and the circular shape is preferred in this embodiment. After the exposure and the developing process, a small photo spacer 500 is formed on the first color resist units 300.

The photo spacer 500 has a shape as shown in FIG. 1, and because of characteristics of the process, is in the form of a frustum of cone which is narrow at the top but wide at the bottom (the aperture B has a circular shape). The height of the photo spacer 500 generally equals to the second color resist units 400. When it is necessary to provide a photo spacer 500 of another height, it can be achieved by adjusting an aperture ratio or an aperture transmissivity of the photomask. Usually, the smaller the aperture ratio of the aperture B, the smaller the height of the photo spacer 500 obtained after the exposure and the developing process.

By forming on the first color resist units a photo spacer for controlling a gap between an array substrate and a color filter substrate simultaneously when the second color resist units is formed, this embodiment of the present invention eliminates the need of the photolithography step as used in the prior art, thereby simplifying the manufacturing process and reducing the cost.

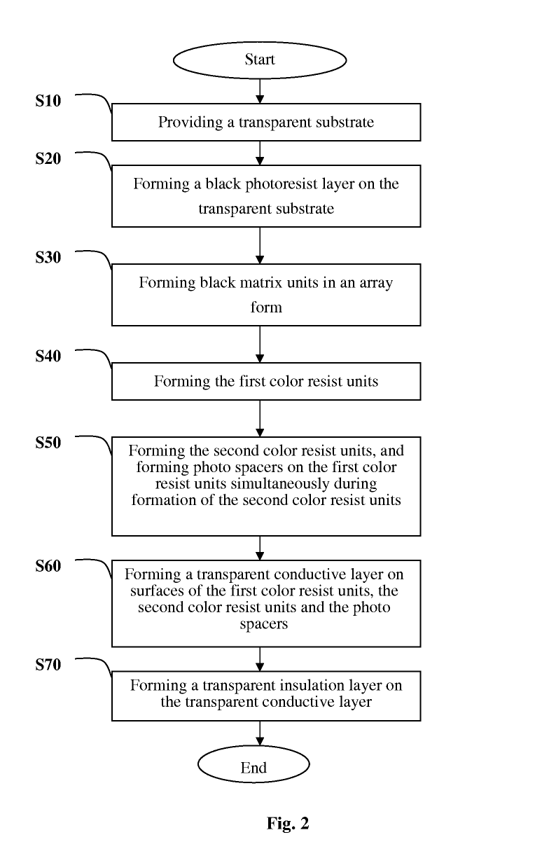

In order to elucidate the manufacturing method of a color filter of the present invention more clearly, the solution of the present invention will be further detailed with reference to FIG. 2. Referring to FIG. 2, there is shown a flowchart illustrating a first embodiment of the manufacturing method of a color filter according to the present invention. The manufacturing method of a color filter comprises the following steps of:

step S10: providing a transparent substrate;

step S20: forming a black photoresist layer on the transparent substrate, and specifically, forming a black photoresist layer on the transparent substrate through coating;

step S30: forming black matrix units in an array form. After the black photoresist layer is formed, the black matrix units in an array form can be obtained through a vacuum drying process, a process for removing the photoresist material at the edges, a pre-baking and cooling process, a exposure process that uses a photomask, a developing process, a baking process, an etching process and a photoresist removing process;

step S40: forming the first color resist units, and specifically, forming a first color resist units in a gap between two black matrix units in a pixel unit. For example, one pixel unit comprises three black matrix units arranged in sequence, a gap exists between any two adjacent black matrix units (i.e., there are two gaps), and the first color resist units is formed in one of the two gaps; and

step S50: forming the second color resist units, and forming on the first color resist units photo spacers for controlling a gap between an array substrate and a color filter substrate simultaneously during formation of the second color resist units, wherein one of the second color resist units is formed in the other one of the two gaps.

The aforesaid method may further comprise:

step S60: forming a transparent conductive layer on surfaces of the first color resist units, the second color resist units and the photo spacers through coating, sputtering or evaporation, wherein the transparent conductive layer covers the black matrix units, the gaps of the black matrix units, and the surfaces of the first color resist units, the second color resist units and the photo spacers; and

step S70: forming a transparent insulation layer on the transparent conductive layer through coating, sputtering or evaporation, wherein the transparent insulation layer can prevent the transparent conductive layer from contacting a thin film transistor (TFT) substrate in the assembling process to cause a short circuit.

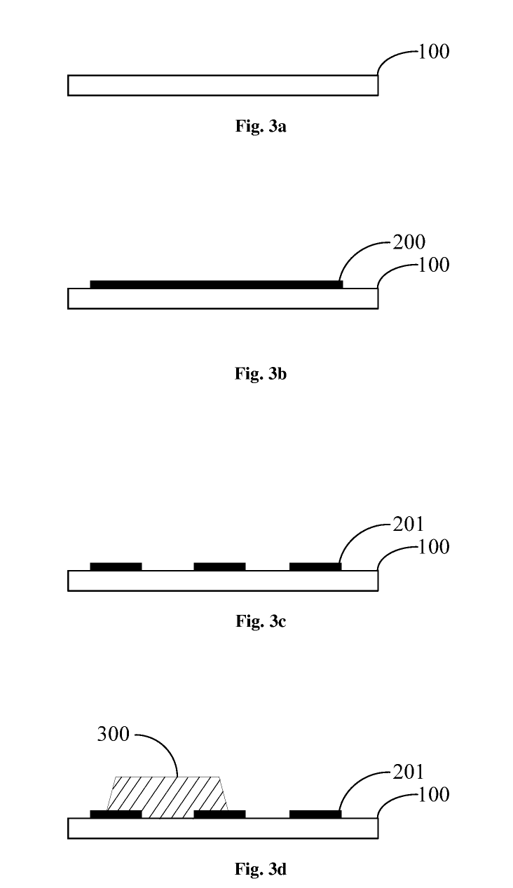

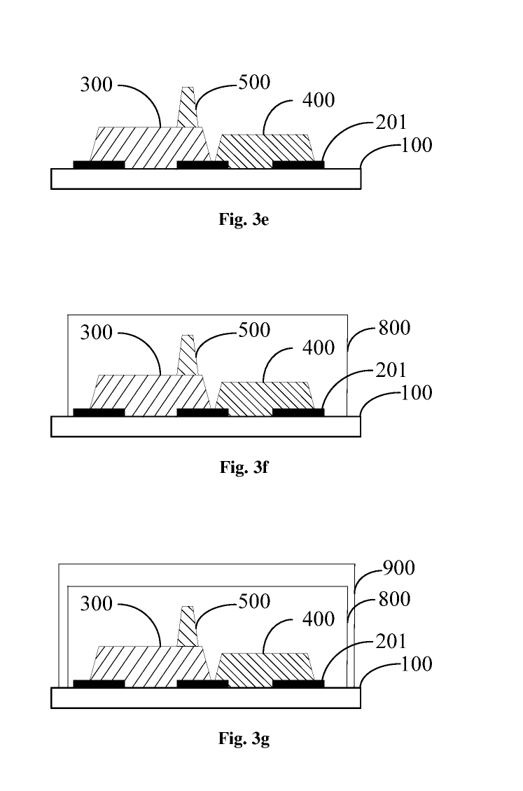

Referring to FIG. 3a to FIG. 3g, there are shown schematic views illustrating a process flow of the aforesaid method according to the present invention.

As shown in FIG. 3a which corresponds to the step S10, a transparent substrate 100 is provided. The transparent substrate 100 is a support of the color filter, and may be made of glass, a transparent hard plastic material or the like.

As shown in FIG. 3b which corresponds to the step S20, a black photoresist layer 200 is formed on the transparent substrate 100.

As shown in FIG. 3c which corresponds to the step S30, the black photoresist layer 200 is patterned to obtain black matrix units 201 in an array form.

As shown in FIG. 3d which corresponds to the step S40, the first color resist units 300 are formed in gaps between the black matrix units 201.

As shown in FIG. 3e which corresponds to the step S50, photo spacers 500 are formed on the first color resist units 300 simultaneously during formation of the second color resist units 400. As shown in FIG. 1, when the second color resist units 400 are formed, and specifically, when a photomask C for forming the second color resist units 400 is placed, the photomask C is additionally formed with a smaller aperture B. A photo spacer 500 is finally formed on one of the first color resist units 300 via the aperture B. For the specific manufacturing process of the photo spacer 500, reference may be made to the aforesaid description with respect to the schematic view of the process flow of forming photo spacers, and no further description will be made herein.

As shown in FIG. 3f which corresponds to the step S60, a transparent conductive layer 800 is formed on surfaces of the first color resist units 300, the second color resist units 400 and the photo spacers 500 through coating, sputtering or evaporation.

As shown in FIG. 3g which corresponds to the step S70, a transparent insulation layer 900 is formed on the transparent conductive layer 800 through coating, sputtering or evaporation.

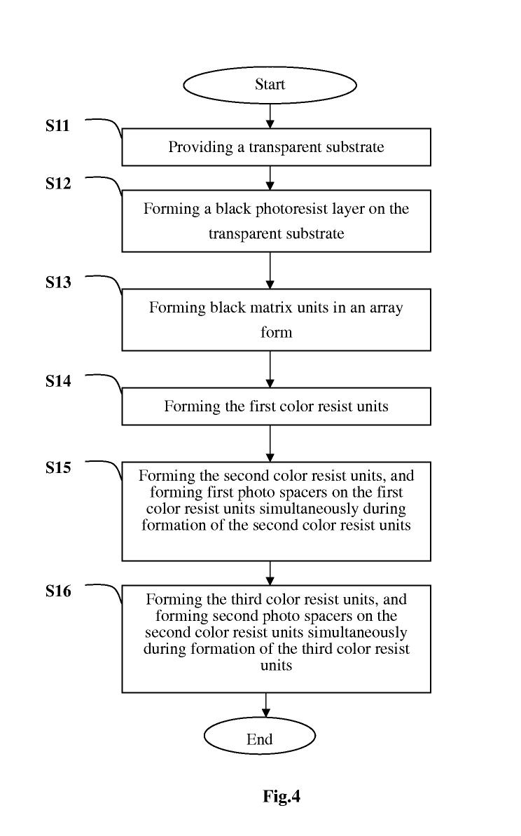

For color filters of the three primary colors (i.e., the red color, the green color and the blue color) currently available, the present invention further provides a manufacturing method of a color filter. Referring to FIG. 4, there is shown a flowchart illustrating a second embodiment of the manufacturing method of a color filter.

In this embodiment, the color filter comprises first color resist units, second color resist units and third color resist units, which are actually red color resist units, green color resist units and blue color resist units. A color pixel unit is formed by one first color resist units, one second color resist units and one third color resist units. As shown in FIG. 4, the manufacturing method of a color filter comprises the following steps of:

step S11: providing a transparent substrate;

step S12: forming a black photoresist layer on the transparent substrate;

step S13: forming black matrix units in an array form;

step S14: forming the first color resist units. For processes of the step S11 to the step S14 in this embodiment, reference may be made to what described with respect to FIG. 2, and FIG. 3a to FIG. 3d in the aforesaid embodiment, and no further description will be made herein;

step S15: forming the second color resist units, and forming first photo spacers on the first color resist units simultaneously during formation of the second color resist units; and

In this embodiment, the colors of the color resist units can be selected by a user depending on actual needs; e.g., the user may designate any one of the red color, the green color and the blue color as the color of the first color resist units, the second color resist units or the third color resist units depending on actual needs. The order in which the first color resist units, the second color resist units and the third color resist units are manufactured may also be determined by the user depending on actual needs, and the present invention has no limitation thereon. Hereinafter, the technical solution of this embodiment will be detailed with reference to a case where the first color resist units are of the red color, the second color resist units are of the green color and the third color resist units are of the blue color. Firstly, a transparent substrate is selected. Then, a black photoresist material is coated on the substrate, and is patterned in such a way that it is divided into a plurality of independent black matrix units arranged in an array form. Then, a first color resist units is formed between every two of the black matrix units. When the green second color resist units are formed, green first photo spacers are formed on the red first color resist units. The height of the first photo spacers may be controlled by the aperture ratio or the aperture transmissivity of the photomask to achieve the desired height of the spacers. Specifically, the first color resist units, the second color resist units and the first photo spacers may be formed according to the manufacturing method of a color filter described in the first embodiment.

step S16: forming the third color resist units, and forming second photo spacers on the second color resist units simultaneously during formation of the third color resist units. When the blue third color resist units are formed, the blue second photo spacers are formed on the green second color resist units in place of the conventional two spacer layers. Specifically, the third color resist units and the second photo spacers may also be formed according to the aforesaid embodiment; e.g., through the following steps:

firstly, coating a color photoresist layer (i.e., a whole layer of a third photoresist material) on surfaces of the first color resist units, the second color resist units, the black matrix units and the glass substrate;

carrying out a vacuum drying process on the first color resist units, the black matrix units, the second color resist units and the third color resist units, and removing the unnecessary third photoresist material at the edges;

carrying out a pre-baking and cooling process, and then disposing a photomask above the color photoresist layer for exposure, wherein the photomask is formed with apertures in positions where the third color resist units and the second photo spacers need to be kept;

carrying out a developing process and removing the unnecessary third photoresist material; and

carrying out a baking process to obtain the third color resist units and the second photo spacers at positions corresponding to the positions of the apertures.

Specifically, the aforesaid step S15 comprises:

forming the first photo spacers on regions where the first color resist units overlap the black matrix units. There are multiple optional positions for the first photo spacers; for example, the first photo spacers may be formed in the regions where the first color resist units overlap the black matrix units. Of course, the first photo spacers may also be directly formed in other regions; in this case, the aperture ratio may be affected by the first photo spacers formed in other regions.

Specifically, the aforesaid step S16 comprises:

forming the second photo spacers in regions where the second color resist units overlap the black matrix units. The second photo spacers may optionally be located in the regions where the second color resist units overlap the black matrix units, and may also be directly formed in other regions although this may affect the aperture ratio.

In this embodiment of the present invention, the height of the first photo spacers and that of the second photo spacers may be adjusted depending on the specific process used, and may be set according to the space between the array substrate and the color filter substrate; and the first photo spacers and the second photo spacers are mainly used to support the array substrate and the color filter substrate in order to completely replace the conventional spacer layers. Specifically, the height of the first photo spacers and that of the second photo spacers may be adjusted by adjusting the aperture ratio or the aperture transmissivity of the photomask; i.e., the aforesaid method may further comprise a step of adjusting the height of the first photo spacers or the second photo spacers by means of the photomask.

According to this embodiment of the present invention, two photo spacers are formed on three color resist units; and preferably, a total height of the first photo spacer and the first color resist units is set to be different from a total height of the second photo spacer and the second color resist units. The photo spacer and the color resist unit that have a larger total height can replace the function of the original main spacer layer (Main PS); and the photo spacer and the color resist unit that have a smaller total height can replace the function of the auxiliary spacer layer (Sub PS). Apart from eliminating the need of a photolithography process for forming the original spacers, this method can further reduce the differences in the rotating time and recovery time of liquid crystals and decrease the amount of liquid crystals to be filled.

The manufacturing method of a color filter of the present invention may further comprise the following two steps subsequent to the step S16:

forming a transparent conductive layer on surfaces of the first color resist units, the second color resist units, the third color resist units, the first photo spacers and the second photo spacers, wherein in the aforesaid embodiment, after the color resist units of the three colors are formed, a transparent conductive layer of indium tin oxide (ITO) can be plated on the surfaces of the color resist units; and

disposing a transparent insulation layer on the transparent conductive layer. To prevent the transparent conductive layers of two substrates from being contacted with each other to cause a short circuit during the process of assembling with the substrates, a layer of color resist units is further coated on each of the transparent conductive layers. The color resist units can form a fully covered transparent insulation layer after being baked. Formation of this transparent insulation layer is formed is not only limited to the coating process, but may also be accomplished through sputtering or evaporation.

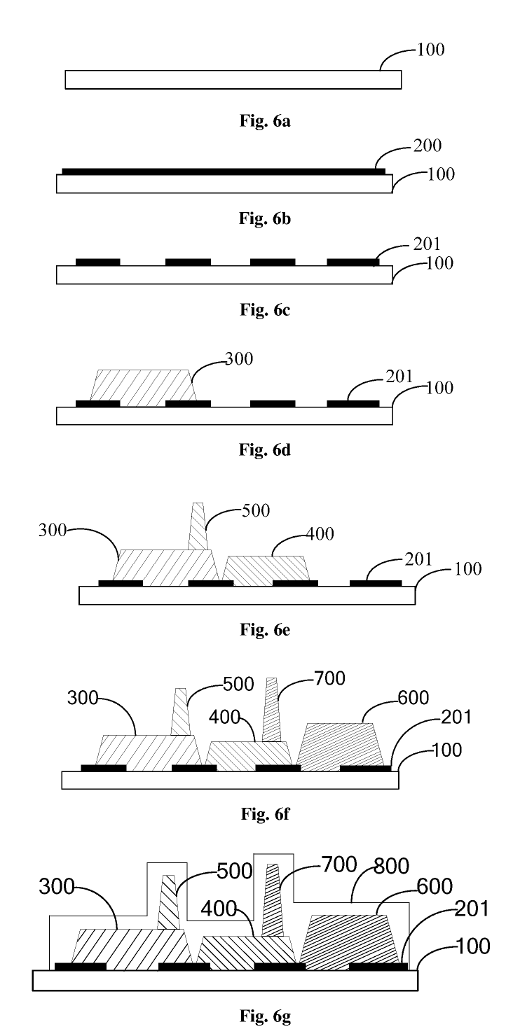

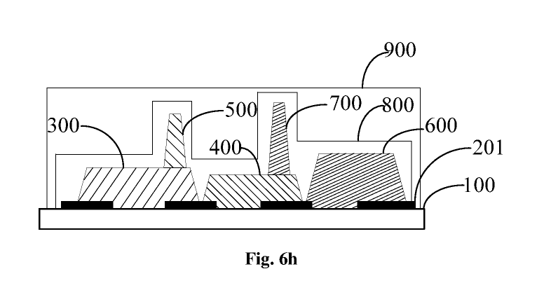

Specifically, referring to FIG. 6, there is shown a flowchart illustrating a third embodiment of the manufacturing method of a color filter according to the present invention. The manufacturing method of a color filter comprises the following steps of:

step S110: providing a transparent substrate;

step S120: forming a black photoresist layer on the transparent substrate;

step S130: forming black matrix units in an array form;

step S140: forming the first color resist units;

step S150: forming the second color resist units, and forming first photo spacers on the first color resist units simultaneously during formation of the second color resist units;

step S160: forming the third color resist units, and forming second photo spacers on the second color resist units simultaneously during formation of the third color resist units;

step S170: forming a transparent conductive layer on surfaces of the first color resist units, the second color resist units, the third color resist units, the first photo spacers and the second photo spacers; and

step S180: forming a transparent insulation layer on the transparent conductive layer.

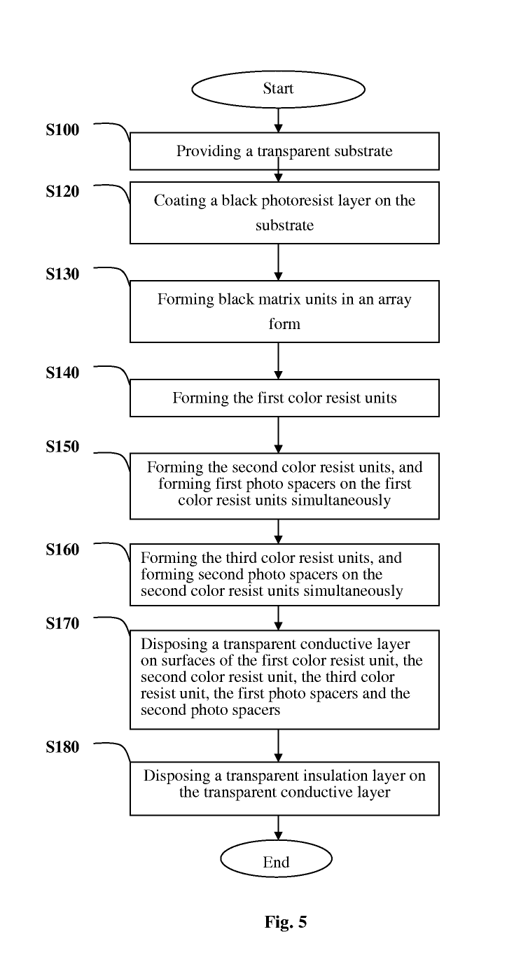

Hereinafter, this embodiment of the present invention will be detailed with reference to FIG. 6a to FIG. 6h. FIG. 6a to FIG. 6h which are schematic views illustrating a process flow of the manufacturing method shown in FIG. 5. The manufacturing process of a color filter of the present invention will be described by taking one pixel unit as an example.

As shown in FIG. 6a which corresponds to the step S110, a transparent substrate 100 is provided. The transparent substrate 100 may be made of but is not limited to glass.

As shown in FIG. 6b which corresponds to the step S120, a black photoresist layer 200 is formed on the transparent substrate.

As shown in FIG. 6c which corresponds to the step S130, the black photoresist layer 200 is patterned to obtain a number of black matrix units 201.

As shown in FIG. 6d which corresponds to the step S140, a first color resist units 300 is formed in a gap between two black matrix units 201. The first color resist units 300 and a second color resist units 400 and a third color resist units 500 that will be described later are disposed in the corresponding gaps of the black matrix units 201 respectively.

As shown in FIG. 6e which corresponds to the step S150, a first photo spacer 500 is formed on the first color resist units 300 simultaneously during formation of the second color resist units 400. The first photo spacer 500, as a spacer, is used to control a gap between the array substrate and the color filter substrate.

As shown in FIG. 6f which corresponds to the step S160, a second photo spacer 700 is formed on the second color resist units 400 simultaneously during formation of the third color resist units 600. The second photo spacer 700, as a subsidiary spacer, is also used to control the gap between the array substrate and the color filter substrate. A total height of the first photo spacer 500 and the first color resist units 300 is usually designed to be different from a total height of the second photo spacer 700 and the second color resist units 400 in order to provide a better supporting effect. Specifically, the height of the first photo spacer 500 or the second photo spacer 700 can be changed by adjusting the aperture ratio or the aperture transmissivity of the photomask.

As shown in FIG. 6g which corresponds to the step S170, a transparent conductive layer 800 is formed (i.e., a transparent conductive layer 800 of ITO is plated) on surfaces of the first color resist units 300, the second color resist units 400, the third color resist units 600, the first photo spacer 500 and the second photo spacer 700.

As shown in FIG. 6h which corresponds to the step S180, a transparent insulation layer 900 is formed on the transparent conductive layer 800.

Referring to FIG. 6f, there is shown a schematic view illustrating a structure of a color filter formed by the aforesaid method. The color filter comprises the first color resist units 300, the second color resist units 400 and the third color resist units 600, and further comprises the first photo spacer 500 and the second photo spacer 700. The first photo spacer 500 is located on the first color resist units 300, and is formed on the surface of the first color resist units 300 during formation of the second color resist units 400; and the second photo spacer 700 is formed on the surface of the second color resist units 400 during formation of the third color resist units 600. A total height of the first photo spacer 500 and the first color resist units 300 is smaller than a total height of the second photo spacer 700 and the second color resist units 400.

Because of characteristics of the manufacturing process, each of the first photo spacer 500 and the second photo spacer 700 is narrow at the top but wide at the bottom in shape, and may have a polygonal, elliptical or circular cross section. In this embodiment, the cross section is designed to be circular; i.e., both the first photo spacer 500 and the second photo spacer 700 are in the form of a frustum of cone. The height of the first photo spacer 500 and that of the second photo spacer 700 may be designed according to the space between the array substrate and the color filter substrate so long as the array substrate and the color filter substrate can be supported. There are multiple options for positions of the first photo spacer 500 and the second photo spacer 700. Preferably, the first photo spacer 500 is formed in a region where the first color resist units 300 overlaps one of the black matrix units 201, and the second photo spacer 700 is formed in a region where the second color resist units 400 overlaps one of the black matrix units 201. Of course, the first photo spacer 500 and the second photo spacer 700 may also be directly formed in other regions, but this will affect the aperture opening ratio.

As shown in FIG. 6f, the transparent substrate 100 has the black matrix units 201 disposed thereon; the black matrix units 201 are coated on the surface of the transparent substrate 100 in an array form; and a gap exists between every two black matrix units 201. The first color resist units 300 are located in a gap between two black matrix units 201. In this embodiment, the colors of the color resist units can be selected by the user depending on actual needs; e.g., the user may designate any one of the red color, the green color and the blue color as the color of the first color resist units 300, the second color resist units 400 or the third color resist units 600 depending on actual needs. The height of the first photo spacer 500 and that of the second photo spacer 700 may be adjusted depending on the specific process used and, in order to completely replace the conventional spacer layers, may be designed according to the space between the array substrate and the color filter substrate so long as the array substrate and the color filter substrate can be supported. Specifically, the height of the first photo spacer 500 and that of the second photo spacer 700 may be adjusted by adjusting the aperture ratio of the photomask.

Referring to FIG. 6h, there is shown another schematic view illustrating a structure of a color filter formed by the aforesaid method.

As compared with the color filter shown in FIG. 6f, the color filter shown in FIG. 6h further comprises a transparent conductive layer 800. The transparent conductive layer 800 is located on the surfaces of the first color resist units 300, the second color resist units 400, the third color resist units 600, the first photo spacer 500 and the second photo spacer 700 and is made of ITO. To prevent the transparent conductive layers 800 of two substrates from being contacted with each other to cause a short circuit during the process of assembling with the substrates, a layer of color resist units is further coated on each of the transparent conductive layers 800. The color resist units can form a transparent insulation layer 900 throughout the surfaces after being baked with heat. Formation of the transparent insulation layer 900 is not only limited to the coating process, but may also be accomplished through sputtering or evaporation.

For the color filter formed by this embodiment of the present invention, a photo spacer is directly formed on a previous color photoresist layer when a next color photoresist layer is formed, and is used to replace the function of a spacer in the prior art. Apart from eliminating the need of a photolithography process for forming the original spacers, this can further reduce the differences in the rotating time and the recovery time of liquid crystals and decrease the amount of liquid crystals to be filled.

The present invention further provides an LCD, which can be applied to an LCD television. In addition to the aforesaid color filter, the LCD further comprises such components as a substrate, a front frame and a light guide plate. Because the structure of the aforesaid color filter is adopted in the LCD, the number of processes for forming the LCD is reduced, the differences in the rotating and the recovery time of liquid crystals are reduced and the amount of liquid crystals to be filled is decreased. Therefore, the manufacturing cost of the LCD is significantly reduced, and competitiveness of the LCD and products thereof in the market is enhanced.

The present invention is not limited to the above embodiments, and various modifications may be made based on the technical disclosures disclosed in these embodiments. Any equivalent structural alterations made based on disclosures of the specification and the attached drawings of the present invention or any direct or indirect applications to other related technical fields are all covered within the scope of the present invention.

1. A manufacturing method of a color filter, wherein the color filter comprises first color resist units and second color resist units, and a pixel layer is formed by the first color resist units and the second color resist units, the manufacturing method comprising the following step of:
after the first color resist units are formed, forming photo spacers for controlling a gap between an array substrate and a color filter substrate simultaneously when the second color resist units are formed.

2. The manufacturing method of claim 1, wherein the step of forming photo spacers for controlling a gap between an array substrate and a color filter substrate simultaneously when the second color resist units are formed comprises:
forming the photo spacers on regions where the first color resist units overlap black matrix units.

3. The manufacturing method of claim 2, wherein the step of forming the photo spacers on regions where the first color resist units overlap black matrix units comprises:
in a photomask for forming the second color resist units, disposing apertures in areas corresponding to the regions where the first color resist units overlap the black matrix units.

4. The manufacturing method of claim 1, wherein the step of forming photo spacers for controlling a gap between an array substrate and a color filter substrate simultaneously when the second color resist units are formed comprises:
disposing apertures for forming the photo spacers in the photomask for forming the second color resist units.

5. A manufacturing method of a color filter, wherein the color filter comprises first color resist units, second color resist units and third color resist units, and a color pixel layer is formed by the first color resist units, the second color resist units and the third color resist units, the manufacturing method comprising the following steps of:
providing a transparent substrate;
forming black matrix units on the transparent substrate;
forming the first color resist units;
forming the second color resist units, and forming first photo spacers on the first color resist units simultaneously during formation of the second color resist units; and
forming the third color resist units, and forming second photo spacers on the second color resist units simultaneously during formation of the third color resist units.

6. The manufacturing method of claim 5, wherein the step of forming the second color resist units and forming first photo spacers on the first color resist units simultaneously during formation of the second color resist units comprises the following steps of:
coating a layer of a second photoresist material on surfaces of the first color resist units, the black matrix units and the transparent substrate;
carrying out a vacuum drying process;
carrying out a pre-baking and cooling process;
disposing a photomask above the second photoresist material for exposure, wherein the photomask is formed with apertures for forming the second color resist units and the first photo spacers; and
carrying out a developing process to form the second color resist units and the first photo spacers.

7. The manufacturing method of claim 5, wherein the step of forming the third color resist units and forming second photo spacers on the second color resist units simultaneously during formation of the third color resist units comprises the following steps of:
coating a layer of a third photoresist material on surfaces of the first color resist units, the second color resist units, the first photo spacers, the black matrix units and the transparent substrate;
carrying out a vacuum drying process;
carrying out a pre-baking and cooling process;
disposing a photomask above the third photoresist material for exposure, wherein the photomask is formed with apertures for forming the third color resist units and the second photo spacers; and
carrying out a developing process to form the third color resist units and the second photo spacers.

8. The manufacturing method of claim 7, wherein when the photomask is disposed for exposure, a height of the first photo spacers or the second photo spacers is controlled by adjusting an aperture ratio or an aperture transmissivity of the photomask.

9. The manufacturing method of claim 5, comprising: forming the first photo spacers on regions where the first color resist units overlap the black matrix units, and forming the second photo spacers on regions where the second color resist units overlap the black matrix units.

10. The manufacturing method of claim 9, wherein the step of forming the first photo spacers on regions where the first color resist units overlap the black matrix units comprises:
in the photomask for forming the second color resist units, disposing apertures in areas corresponding to the regions where the first color resist units overlap the black matrix units.

11. The manufacturing method of claim 9, wherein the step of forming the second photo spacers on regions where the second color resist units overlap the black matrix units comprises:
in the photomask for forming the third color resist units, disposing apertures in areas corresponding to the regions where the second color resist units overlap the black matrix units.

12. The manufacturing method of claim 5, further comprising the following steps of:
forming a transparent conductive layer on surfaces of the first color resist units, the second color resist units, the third color resist units, the first photo spacers and the second photo spacers; and
forming a transparent insulation layer on the transparent conductive layer.

13. A color filter, comprising:
a substrate;
a plurality of black matrix units, being disposed on the substrate in an array form, wherein gaps exist between adjacent ones of the black matrix units;
a plurality of first color resist units, a plurality of second color resist units and a plurality of third color resist units, being located in the gaps between the black matrix units and disposed adjacent to each other in sequence to form a pixel layer;
first photo spacers, being formed on surfaces of the first color resist units when the second color resist units are formed, and being located in regions where the first color resist units overlap the black matrix units;
second photo spacers, being formed on surfaces of the second color resist units when the third color resist units are formed, and being located in regions where the second color resist units overlap the black matrix units;
a transparent conductive layer covering the surfaces of the first color resist units, the second color resist units, the third color resist units, the first photo spacers and the second photo spacers; and
a transparent insulation layer covering the transparent conductive layer.

14. The color filter of claim 13, wherein a total height of one of the first photo spacers and one of the first color resist units is different from a total height of one of the second photo spacers and one of the second color resist units.

15. The color filter of claim 13, wherein each of the first photo spacers and the second photo spacers is in the form of a frustum of cone which is narrow at the top but wide at the bottom.
